(19) United States
(12) Patent Application Publication
(10) Pub. No.: US 2006/0120191 A1
(43) Pub. Date: Jun. 8, 2006

(54) Systems and methods for optical drive operation

(75) Inventors: Shr-Cheng Li, Taipei (TW); Chin-Sung Lee, Kaohsiung Hsien (TW); Chia-Wen Lee, Luzhou City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Mediatek Incorporation

(21) Appl. No.: 11/053,565

(22) Filed: Feb. 8, 2005

Related U.S. Application Data
(60) Provisional application No. 60/633,596, filed on Dec. 6, 2004.

(51) Int. Cl. G11C 13/04

(52) U.S. Cl. 365/215

(57) ABSTRACT

A system for relocating code. A first memory stores a plurality of original code modules. A second memory stores a copied code module duplicated from one of the original code modules. A microprocessor retrieves and executes the retrieved code modules. A retrieval controller directs the retrieve operation of the microprocessor according to a preset rule. The microprocessor also executes basic operations, and determines whether media and corresponding operational firmware are present therein. An interface receives data comprising operational firmware from a host when media is present without corresponding operational firmware. The second memory also stores the received operational firmware, which directs the processor to operate.

### BACKGROUND

The invention relates to optical drive operation, and more particularly to providing relocatable code thereby permitting an optical drive to operate reliably and efficiently with code stored in a plurality of separate internal storage devices.

FIG. 1 is a schematic view of a conventional optical drive 10, comprising a microprocessor 11, random access memory (RAM) 15, read only memory (ROM) 13, read/write unit 19, and host interface 17. The microprocessor 11 controls operations of read/write unit 19 according to instruction code stored in the ROM 13. When media is loaded onto optical drive 10, microprocessor 11 directs read/write unit 19 to retrieve data from the media, and the retrieved data is temporarily stored in RAM 15 before output to a host 12 through the host interface 17. When writing, data is sent from the host 12 to the optical drive 10 through the host interface 17, stored temporarily in the RAM 15, and written to media under the control of the microprocessor 11 according to the instruction code stored in ROM 13. Typically, the ROM 13 stores instruction code, and the RAM 15 temporarily stores data required during operations. As functions of optical drives increase, the instruction code required increases as well, as does bandwidth required to transfer the instruction code from ROM 13 to microprocessor 11. The ROM in an optical drive may be a flash ROM, EEPROM, or other type of non-volatile memory. A typical non-volatile memory is parallel flash ROM, which provides wider bandwidth, thereby enabling better performance. Parallel flash ROM, however, occupies substantial layout space, requires substantial power, and consumes substantial resources during manufacture.

Recently, serial Flash ROM has been developed. Compared with the parallel Flash ROM, the serial Flash ROM occupies less layout space, requires less power, and consumes fewer resources during manufacture. Serial Flash ROM, however, is unable to provide sufficient bandwidth and may therefore be detrimental to performance.

Additionally, as functionality of optical drives grows, firmware required becomes more complex, with costs of optical drives increasing with storage capacity of ROM therein.

### SUMMARY

Systems and methods for relocating code are provided. An embodiment of an optical drive comprises a first memory, second memory, microprocessor, and a retrieval controller. The first memory stores a plurality of original code modules. The second memory stores a code module duplicated from one of the original code modules. The microprocessor retrieves the code modules from either the first memory or the second memory and executes the retrieved code modules. The retrieval controller directs the microprocessor to retrieve the code modules according to a preset rule.

Also disclosed are methods of relocating code in an optical drive, wherein the optical drive comprises a first memory and a second memory. In an embodiment of such a method, a plurality of original code modules are provided in the first memory. One of the original code modules is duplicated, and the copied code module is stored in the second memory. Locations of the original and copied code modules in the first memory and second memory are identified. The original and copied code modules are retrieved according to a preset rule, wherein the copied code module is retrieved if present, otherwise the original code module is retrieved instead. The retrieved code module is then executed.

Optical drives are provided. In embodiments of an optical drive comprising a processor, interface, and volatile memory, the processor executes basic operations, and determines whether media and corresponding operational firmware are present therein. The interface receives data comprising operational firmware from a host when media is present without corresponding operational firmware. The volatile memory stores the received operational firmware, which directs the processor to operate.

Also disclosed are methods of inputting firmware in optical drives. In embodiments of such a method, basic operations provided by the optical drive are performed. It is determined whether media is present, and if so, it is further determined whether operational firmware corresponding thereto is present in the volatile memory. If no operational firmware is found, data comprising operational firmware is received from a host, stored in the volatile memory, and used for later operations.

A basic firmware module and plurality of operational firmware modules may also be provided in operational firmware.

### DESCRIPTION OF THE DRAWINGS

Systems and methods for relocating code therein can be more fully understood by reading the subsequent detailed description and examples with references made to the accompanying drawings, wherein:

FIG. 1 is a schematic view of a conventional optical drive;

FIG. 2 is a schematic view of an embodiment of an optical drive;

FIG. 3 is a flowchart of an embodiment of a method for relocating code;

FIG. 4 is a schematic view of an embodiment of code locations in optical drives;

FIGS. 5A and 5B are flowcharts of an embodiment of a method for relocating code in optical drives during sleep and wake-up modes;

FIG. 6 is a schematic view of an embodiment of a system for optical drive operation;

FIG. 7 is a flowchart of an embodiment of a method for operation of an optical drive without a ROM;

FIG. 8 is a schematic view of an embodiment of a system for optical drive operation; and

FIG. 9 is a flowchart of an embodiment of a method for operation of an optical drive equipped with a ROM.

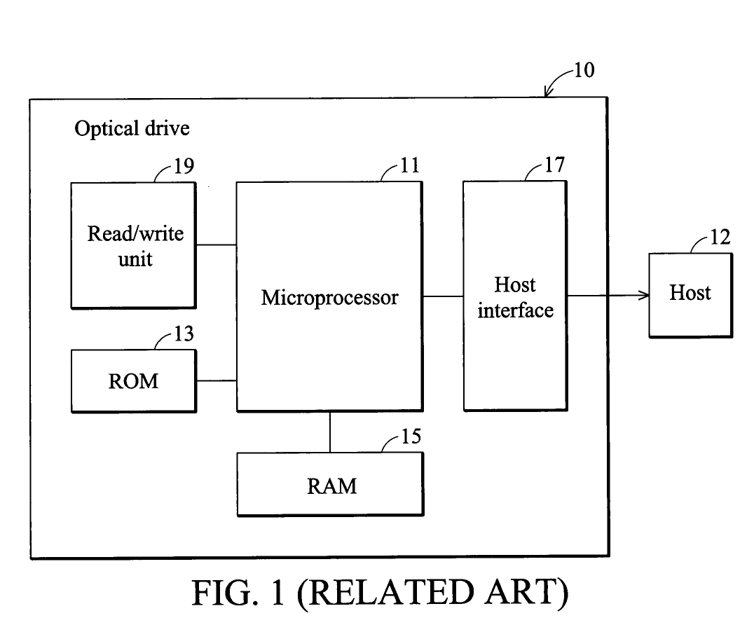

### DETAILED DESCRIPTION

While applicable to an optical drive, it is understood that the invention is not limited thereto, and other peripheral devices may be readily substituted.

In the following detailed description, reference is made to the accompanying drawings which form a part hereof, and in which is shown by way of illustration of specific embodiments. These embodiments are described in sufficient detail to enable those skilled in the art to practice the disclosure, and it is to be understood that-other embodiments may be utilized and structural, logical and electrical changes may be made without departing from the spirit and scope of the disclosure. The following detailed description is, therefore, not to be taken in a limiting sense. The leading digit(s) of reference numbers appearing in the Figures corresponds to the Figure number, with the exception that the same reference number is used throughout to refer to an identical component which appears in multiple Figures.

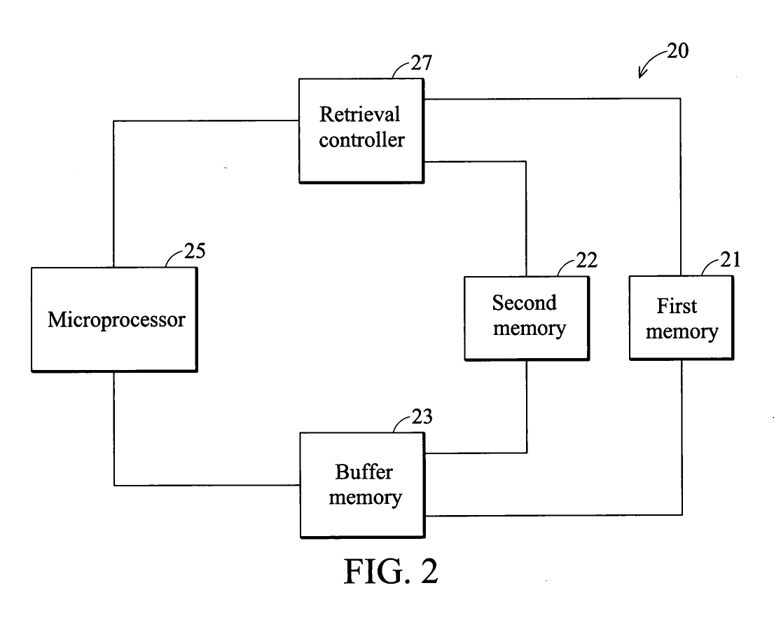

FIG. 2 is a schematic view of an embodiment of an optical drive 20 capable of relocating code, comprising a first memory 21, second memory 22, buffer memory 23, microprocessor 25, and retrieval controller 27.

The first memory 21 stores a plurality of original code modules directing various operations of optical drive 20. For a microprocessor such as 8051uP, each code module comprises 64 Kbytes of code, which is a basic unit of information manipulation for the particular microprocessor. Here, the first memory 21 is serial read only memory (ROM), while the second memory 22 is dynamic random access memory (DRAM), static random access memory (SRAM) or other types of memory. In some embodiments, the first memory 21 stores up to 64 code modules (or “banks”), each corresponding to a serial number.

The second memory 22 stores data and at least one copied code module duplicated from one of the original code modules. The second memory 22 is redownloaded in response to a predetermined event, such as initiation and/or waking-up from a sleep mode.

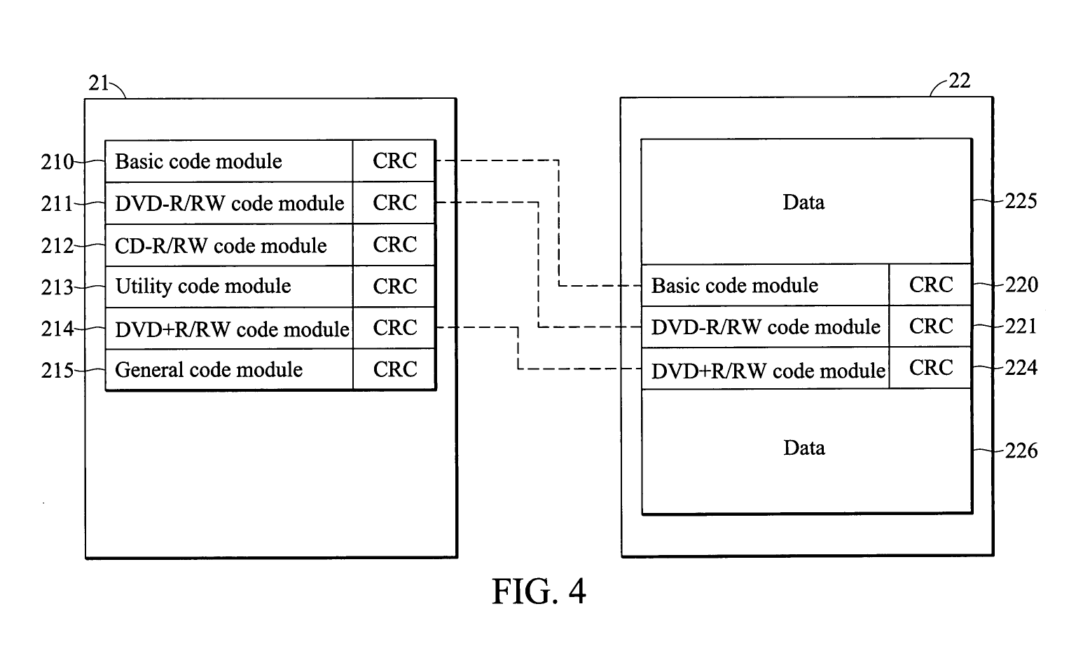

Referring to FIG. 4, the first memory is serial Flash ROM storing code modules 210 215 in sequential organization, comprising a basic code module 210, DVD-R/RW code module 211, CD-R/RW code module 212, utility code module 213, DVD+R/RW code module 214, and general code module 215, each of which comprises accompanying Cyclic Redundancy Check (CRC) information. The CRC information may be used later for a CRC error checking process. The first memory is formatted according to the microprocessor operating therewith.

The code modules to be duplicated are predetermined. For example, code modules pertaining to manipulating a particular type of media are to be duplicated. Here, the basic code module 210, DVD-R/RW code module 211, and DVD+R/RW code module 214 are duplicated to generate copied code modules 220, 221, and 224 respectively. The duplication policy may be defined to meet special requirements, and is not limited to the described example. As shown in FIG. 4, second memory 22 stores copied code modules 220, 221, and 224 together with other data 225 and 226, such as data read from media present in the optical drive.

The buffer memory 23 temporarily stores the retrieved code modules. The microprocessor 25 retrieves the code modules from the buffer memory 23 and executes the retrieved code modules. The retrieval controller 27 directs the microprocessor 25 to retrieve code modules from either the first memory or the second memory according to a preset rule. In some embodiments, the preset rule directs the microprocessor to retrieve the copied code modules stored in the second memory 22 when the copied code modules are present, otherwise to the original code modules stored in the first memory 21. The retrieval controller 27 determines whether the code module to be retrieved has a corresponding copied code module stored in the second memory 22. Additionally, the retrieval controller 27 adjusts bandwidth used for retrieving code module from the second memory, thus the code retrieving operation does not impact other operations.

Here, the buffer memory 23 is similar to a FIFO (First-in-First-Out) memory. The buffer memory 23 uses a bottom address to record the first instruction's position (IP) fetched-in and a top address to record the last IP fetched-in. When the microprocessor 25 tries to request an instruction located inside the range between the top address and the bottom address, the buffer memory 23 will return the requested instruction directly. When the requested IP is not inside the recorded range, the buffer memory 23 resets itself and refills the memory as much as possible (or till the capacity of the buffer memory 23 is full). After the resetting process, the bottom address is equivalent to a top address pointer. During the refilling process, the buffer memory fetches the instructions with continuous IP's and the top address is incremented by one when fetching another instruction into the memory.

Additionally, the optical drive 20 may comprise more than two storage devices, and the code relocation among separate storage devices is performed according to the preset rule, which may be defined to meet special requirements.

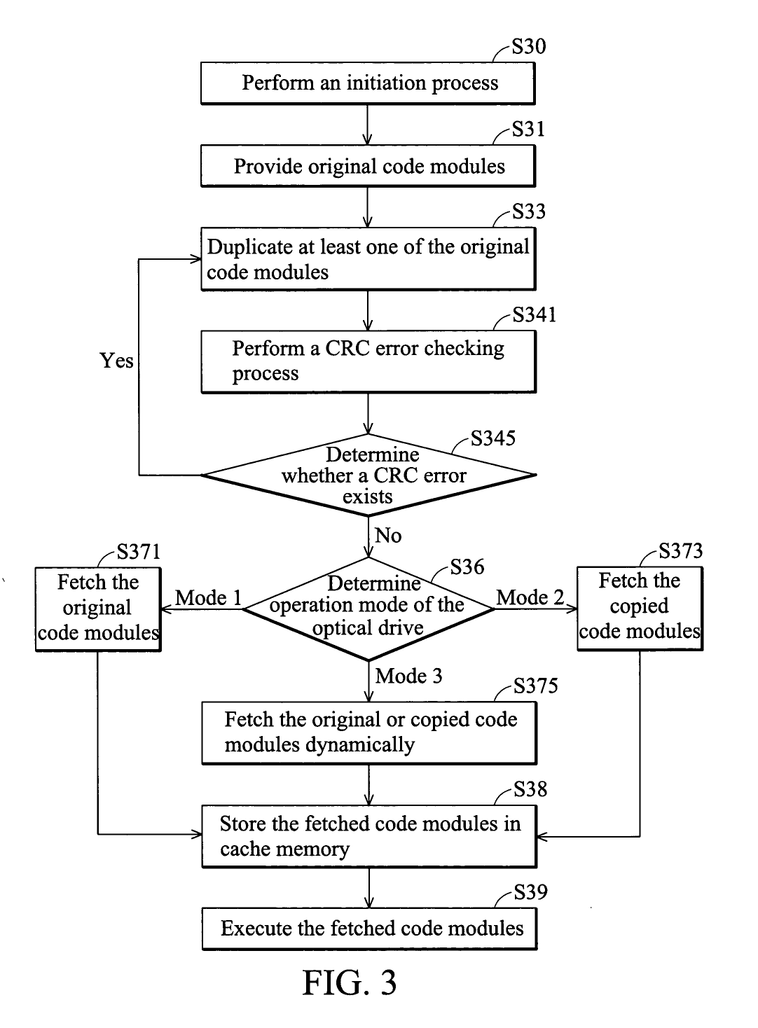

The code relocation implemented in optical drive 20 is detailed in the flowchart of FIG. 3. In step S30, an initiation process is performed responsive to a preset event, such as media presents in the optical drive, provided media is changed, a cache miss event occurs, and other event defined to meet special requirements. A plurality of original code modules are provided in the first memory (step S31). Referring to FIG. 4, the first memory is serial Flash ROM storing code modules 210 215 in sequential organization, comprising a basic code module 210, DVD-R/RW code module 211, CD-R/RW code module 212, utility code module 213, DVD+R/RW code module 214, and general code module 215, and each of which comprises accompanying Cyclic Redundancy Check (CRC) information. The CRC information may be used later for a CRC error checking process. The first memory is formatted according to the microprocessor operating therewith. Here the microprocessor is 8051 uP, wherein each code module comprises 64 Kbytes of code, which is a basic unit for information manipulation for the particular microprocessor.

At least one of the original code modules is duplicated, and the copied code module is stored in the second memory (step S33). The code modules to be duplicated are predetermined. For example, code modules pertaining to manipulating a particular type of media are to be duplicated. Here, the basic code module 210, DVD-R/RW code module 211, and DVD+R/RW code module 214 are duplicated to generate copied code modules 220, 221, and 224. The duplication policy may be defined to meet special requirements, and is not limited to the described example. The second memory 22 is dynamic random access memory (DRAM), static random access memory (SRAM) or other types of memory. As shown in FIG. 4, second memory 22 stores copied code modules 220, 221, and 224 together with other data 225 and 226, such as data read from media present in the optical drive.

Additionally, microprocessor operations may be suspended while the duplication process is in progress, and may resume its operations when the duplication process is finished.

In step S341, a CRC error checking process is performed using the CRC information attached to each of the code modules 210 215, and 220, 221, and 224. The CRC checking process checks whether the code modules are correctly duplicated. Instep S345, it is determined whether a CRC error exists, and if so, the method returns to step S33, if not, the method proceeds to step S36.

In step S36, it is determined, as a preset rule for example, whether the optical drive is set in mode 1, 2, or 3. For mode 1, the method proceeds to step S371, wherein original code modules stored in the first memory (ROM) are retrieved. For mode 2, the method proceeds to step S373, wherein the copied code modules stored in the second memory (RAM) are retrieved. For mode 3, the method proceeds to step S375, wherein either the original or the copied code modules are retrieved according to a preset rule. Here, the code modules 210, 211, and 214 have corresponding copied code modules 220, 221, and 224. Retrieving operations may be switched dynamically between the original or copied code modules according to the preset rule. The preset rule may be set to meet special requirements. For example, the preset rule directs the retrieving operation to the copied code module stored in the second memory 22 when the copied code module exists, otherwise to the original code modules stored in the first memory 21. When bandwidth of the second memory is insufficient for code retrieving, the original code modules may be retrieved instead.

The retrieved code modules may be stored temporarily in buffer memory 23 (step S38). Bandwidth used to transmit code modules from the second memory to the buffer memory may be adjusted dynamically.

In step S39, the retrieved code modules are executed.

There is another way to decide the code banks needed to download from the first memory to the second memory. The firmware builds a table to record each subroutine's information including the subroutine's caller and the related subroutine's call and the number of code banks. When a subroutine is called, the table is analyzed by firmware to identify possible calling sequences and the code banks used. If the possible code banks are not located inside the second memory, the firmware can download these code banks from the first memory to the second memory.

There is also another way to decide the codes needed to download from the first memory to the second memory. The codes can be try-run once before the codes are run at the second memory. Once some codes have been executed at the try-run stage, the codes are loaded into the second memory. In other words, while the codes are run, all the codes needed have been loaded into the second memory. This method is likely to take the second memory as a very large cache memory, loading all of the needed codes into the second memory at the try-run stage, and running the codes without cache miss at the second memory.

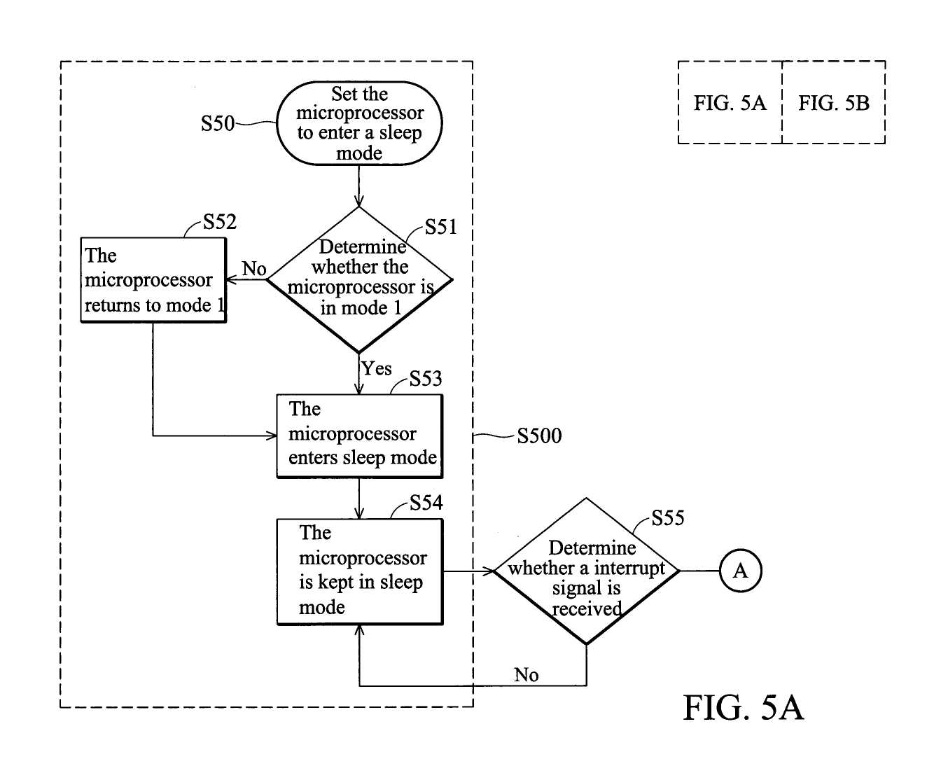

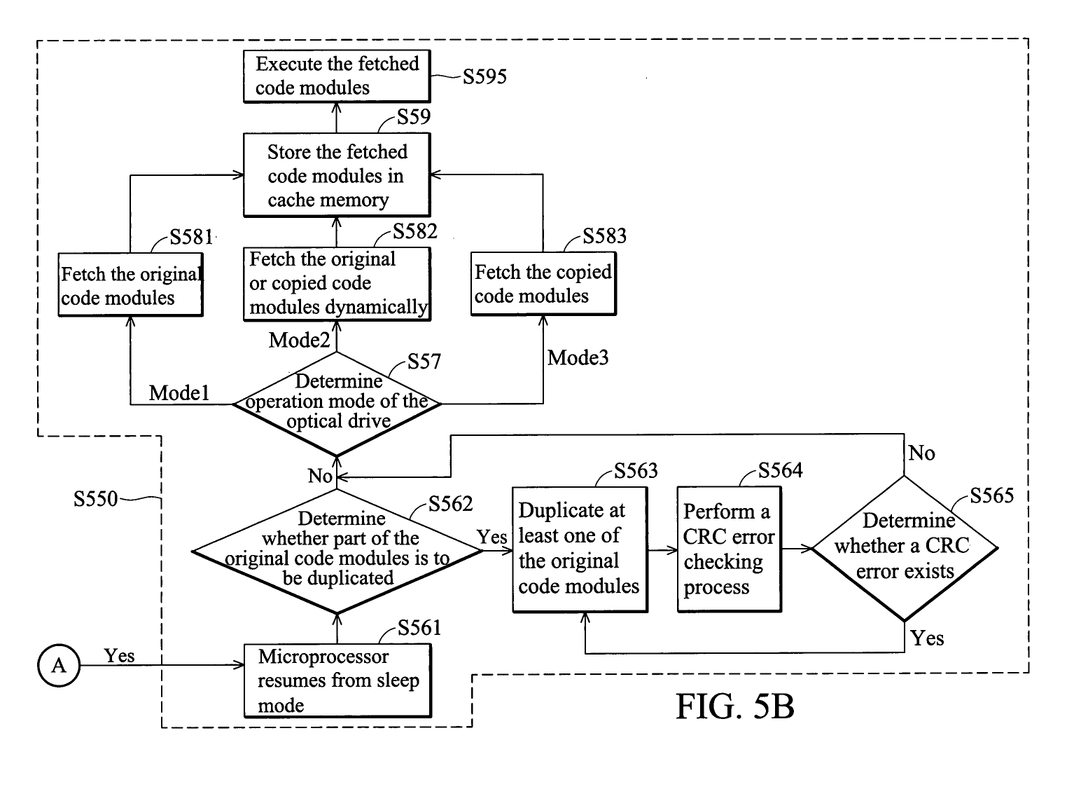

Typically, an optical drive enters a low-power sleep mode to conserve power when not in use. Before entering a sleep mode, the microprocessor returns to mode 1, wherein original code modules stored in the first memory (ROM) are retrieved. The code relocation implemented during a sleep mode S500 and a wake up mode S550 is detailed in FIG. 5. Referring to FIG. 5, in step S50, the microprocessor is set to enter a sleep mode. In step S51, it is determined whether the microprocessor is in mode 1, and if so, the method proceeds to step S53, if not, the microprocessor returns to mode 1 (step S52). In step S53, the microprocessor enters sleep mode. In step S54, the microprocessor is kept in sleep mode. The duration of the sleep mode may be too long for the second memory (RAM) to keep the code modules intact. Therefore, if the microprocessor does not return to mode 1 before entering a sleep mode, errors may be incurred when retrieving code modules when the microprocessor waking up from sleep mode. The microprocessor returns to mode 1 before entering sleep mode to make sure that intact code modules can be retrieved when the microprocessor wakes up from sleep mode. In step S55, it is determined whether a signal has been received to interrupt sleep mode, and if so, the method proceeds to step S561, otherwise the method returns to step S54. In step S561, the microprocessor wakes from sleep mode. In step S562, it is determined whether part of the original code modules is to be duplicated, and if so, the method proceeds to step S563, otherwise the method proceeds to step S57. In step S563, at least one of the original code modules are duplicated. The code modules to be duplicated are predetermined. For example, code modules pertaining to manipulating a particular type of media are to be duplicated. Here, the basic code module 210, DVD-R/RW code module 211, and DVD+R/RW code module 214 are duplicated to generate copied code modules 220, 221, and 224. The duplication policy may be defined to meet special requirements, and is not limited to the described example. In step S564, a CRC error checking process is performed using the CRC information attached to each of the code modules. The CRC checking process checks whether the code modules are correctly duplicated. In step S565, it is determined whether a CRC error exists, and if so, the method returns to step S563, if not, the method proceeds to step S57. Original code modules having corresponding copies are identified, as well as the locations of the original and copied code modules.

In step S57, it is determined whether the optical drive is set in mode 1, 2, or 3. For mode 1, the method proceeds to step S581, wherein original code modules stored in the first memory (ROM) are retrieved. For mode 2, the method proceeds to step S582, wherein the copied code modules stored in the second memory (RAM) are retrieved. For mode 3, the method proceeds to step S583, wherein either the original or the copied code modules are retrieved according to a preset rule. Here, the code modules 210, 211, and 214 have corresponding copied code modules 220, 221, and 224. Whether the original or copied code modules are to be retrieved may be determined according to the preset rule. The preset rule may be set to meet special requirements. For example, the preset rule directs the retrieving operation to the copied code module stored in the second memory 22 when the copied code module exists, otherwise to the original code modules stored in the first memory 21. When bandwidth of the second memory is insufficient to retrieve code, the original code modules may be retrieved instead.

The retrieved code modules may be stored temporarily in buffer memory 23 (step S59). In step S595, the retrieved code modules are executed.

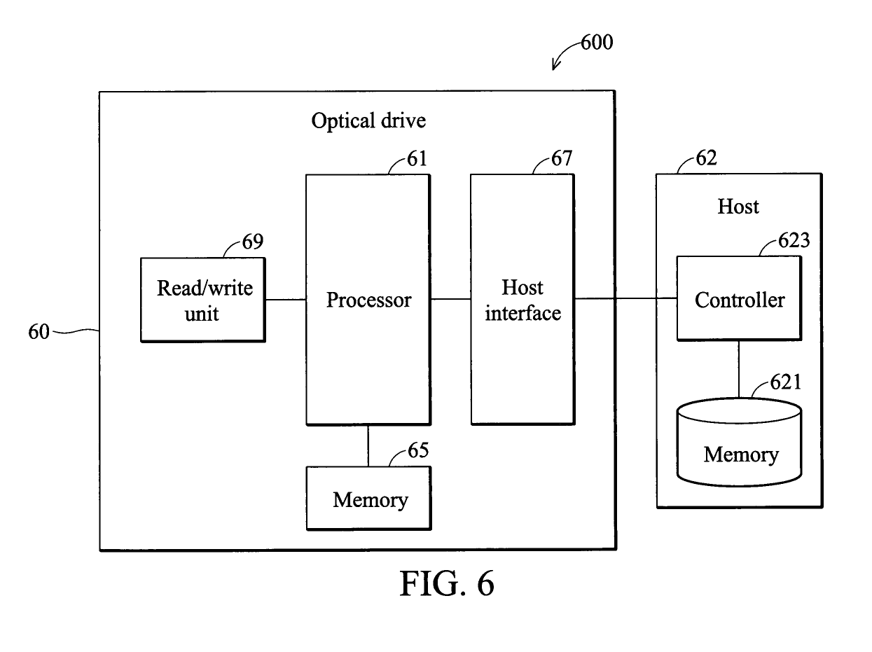

FIG. 6 is a schematic view of an embodiment of a system 600 for inputting firmware, comprising a host 62 and optical drive 60. The optical drive 60 comprises a processor 61, memory 65, host interface 67, and read/write unit 69. The processor 61 controls operation of read/write unit 69 according to firmware stored in memory 65. The memory 65 may be a dynamic random access memory (DRAM), or other type of volatile memory. The optical drive 60 connects to host 62 via the host interface 67. The host 62 may be a personal computer or other information handling system capable of serving as a host, comprising a memory 621 and a controller 623. The memory 621 stores firmware directing operation of the optical drive 60, which may comprise a plurality of firmware modules, each comprising instruction codes for a particular function of the optical drive 60. Typically, there are basic and operational firmware modules, with the basic firmware module directing basic operations of the optical drive, and operational modules directing functional operations of the optical drive, such as retrieving data from and writing data to media, or other designated functional operations. Controller 623 controls input of firmware modules to the optical drive 60. The processor 61 executes basic operations, comprising determination of whether media and corresponding operational firmware are present, and determining characteristics of any media present. The basic operations are executed according to the basic firmware module input from the host 62. The interface 67 receives data for the operational firmware from host 62 when media is present without corresponding operational firmware modules in the memory 65. The memory 65 stores the received operational firmware modules.

When data retrieval is performed, the optical drive 60 enters a firmware input mode, and a basic firmware module is input from host 62 to memory 65 via host interface 67. The basic firmware module directs processor 61 to perform corresponding basic operations. When media is present in the optical drive 60, host 62 transmits selected operational firmware to optical drive 60. The received operational firmware module is stored in memory 65, directing processor 61 to control read operations to retrieve data from the media. The retrieved data is stored temporarily in memory 65 before output to host 62 through the host interface 67. To write to the media, another operational firmware module is received from host 62 to optical drive 60 via host interface 67. Data to be written is temporarily stored in memory 65 before writing to the media. The received operational firmware module is stored in the memory 65, directing processor 61 to control write operations to write the data to the media.

The number of memory devices equipped within optical drive 60 is not limited. The optical drive 60 may comprise more than two memory devices, and retrieve instruction codes from various memory devices.

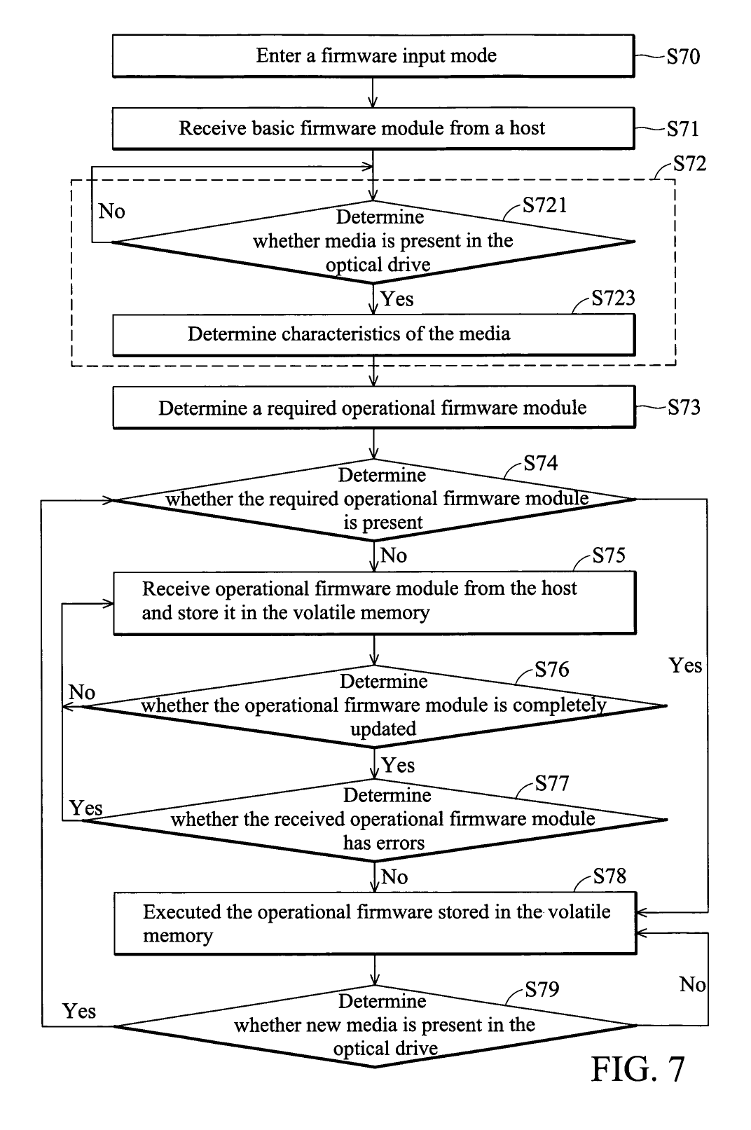

The firmware input process implemented in host 62 and optical drive 60 is detailed in the flowchart of FIG. 7. An optical drive enters a firmware input mode according to a request (step S70), such as a user command or in response to a preset system event, such as power-up. The optical drive is configured for firmware input when it has entered the firmware input mode.

A basic firmware module is input from a host (step S71), and stored in a volatile memory of the optical drive, with a basic operation performed according thereto (step S72). First, it is determined whether media is present in the optical drive (step S721), and if so, characteristics thereof are determined (step S723). Different operational firmware modules manipulate media having different characteristics. For example, the optical drive may perform data retrieval from DVD and VCD based on dedicated operational firmware modules. Additionally, operations of different functions require different operational firmware modules.

A requirement is determined for a special operational firmware module (step S73), and whether the required module is present (step S74). If so, the method proceeds to step S78. If not, it is received from the host and stored in the volatile memory (step S75). Once the required operational firmware module is completely input from the host (step S76), the method proceeds to step S78, wherein it is determined whether the received module has errors (step S77), and if so, the method returns to step S75. If not, the method proceeds to step S78, wherein the recorded operational firmware is executed. In step S79, it is determined whether new media is present in the optical drive, and if so, the method returns to step S74, if not, the method returns to step S78.

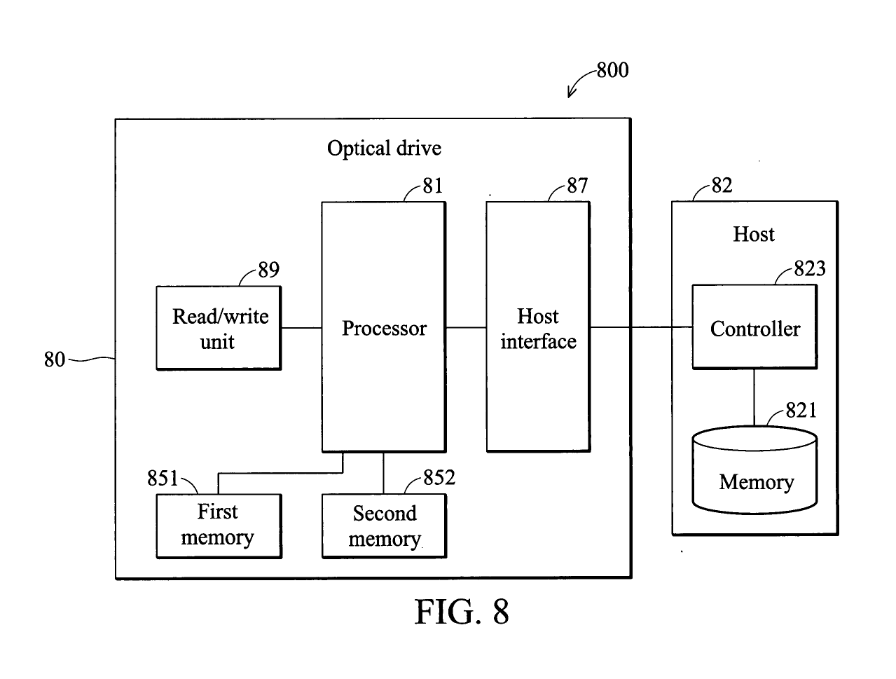

Here, the optical drive does not comprise a non-volatile memory, and uses volatile memory to store basic and operational firmware modules. Additionally, the optical drive may comprise both volatile and non-volatile memory, such that the non-volatile memory stores the basic firmware module directing the basic operations of the optical drive. When media is present in the optical drive, a required operational firmware module is input from a host to the volatile memory. Since the non-volatile memory is not required to store the operational firmware module, requirements of memory capacity are reduced. FIG. 8 is a schematic view of a system for inputting firmware, wherein the optical drive is equipped with a small non-volatile memory. A system 800 comprises a host 82 and optical drive 80. The optical drive 80 comprises a processor 41, first memory 851, second memory 852, host interface 87, and read/write unit 89. The first memory 851 stores basic firmware, and may be flash ROM, EEPROM, or other kinds of memory. The second memory 852 stores operational firmware, and may be dynamic random access memory (DRAM), or other kinds of memory. The optical drive 80 connects to host 82 via the host interface 87. The processor 81 executes basic operations according to the basic firmware stored in the first memory 851, such as determining whether a disc and corresponding operational firmware are present. The interface 87 receives data comprising operational firmware from host 82 when the optical disc is present without corresponding operational firmware. The processor 81 establishes a firmware map identifying storage locations of the basic firmware and the operational firmware, respectively. The processor 81 controls operations of read/write unit 89 according to operational firmware stored in second memory 852. The host 82 may be a personal computer or other information handling system capable of serving as a host, comprising a memory 821 and a controller 823.

The memory 821 stores firmware directing operation of the optical drive 80, which may comprise a plurality of firmware modules, each comprising instruction codes for a particular function of the optical drive 80. Typically, there are basic and operational firmware modules, with the basic firmware module directing basic operations of the optical drive, and operational modules directing functional operations of the optical drive, such as retrieving data from and writing data to media, or other designated functional operations. The controller 823 controls input of firmware modules to the optical drive 80.

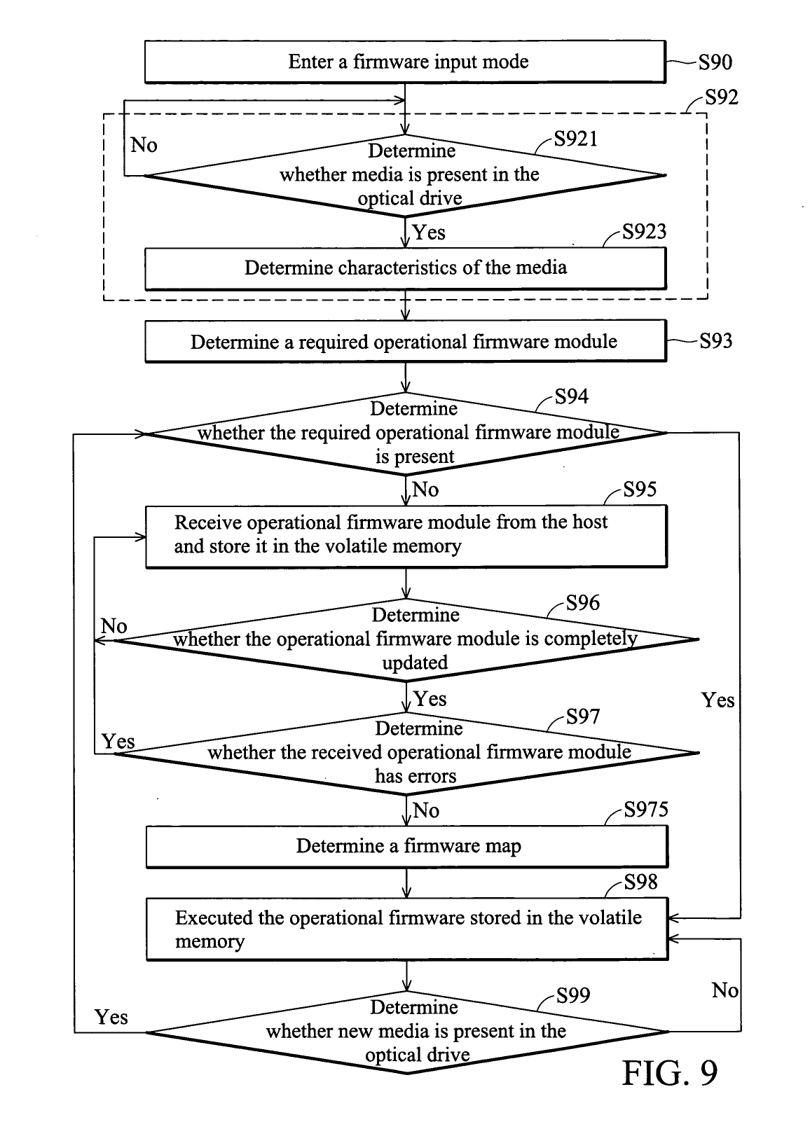

The firmware input process implemented in host 82 and optical drive 80 is detailed in the flowchart of FIG. 9.

An optical drive enters a firmware input mode according to a request (step S90), such as a user command or in response to a preset system event, such as power-up. The optical drive is configured for firmware input when it has entered the firmware input mode.

Basic operations are performed according to the basic firmware stored in the non-volatile memory (step S92). First, it is determined whether media is present in the optical drive (step S921), and if so, characteristics thereof are determined (step S923). Different operational firmware modules manipulate media having different characteristics. For example, the optical drive may perform data retrieval from DVD and VCD based on dedicated operational firmware modules.

A requirement is determined for a special operational firmware module (step S93), and whether the required module is present (step S94). If so, the method proceeds to step S98. If not, it is received from the host and stored in the volatile memory (step S95). Once the required operational firmware module is completely input from the host (step S96), the method proceeds to step S98, wherein it is determined whether the received module has errors (step S97), and if so, the method returns to step S95. If not, the method proceeds to step S98, wherein the recorded operational firmware is executed. In step S975, a firmware map is established, identifying storage locations of the basic firmware and the operational firmware, respectively. In step S99, it is determined whether new media is present in the optical drive, and if so, the method returns to step S94, if not, the method returns to step S98.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A method of operating an optical drive comprising a first memory and a second memory, the method comprising:
providing a plurality of original code modules in the first memory;
duplicating one of the original code modules to generate a copy thereof and storing the copied code module in the second memory;
retrieving the original or copied code modules according to a preset rule; and
executing the retrieved code modules.

2. The method of claim 1, wherein the first memory is a serial flash memory.

3. The method of claim 1, wherein the second memory is a random access memory (RAM).

4. The method of claim 1, wherein the code module duplication is performed in response to a predetermined event.

5. The method of claim 4, wherein the predetermined event is initiation of the optical drive.

6. The method of claim 4, wherein the predetermined event is the optical drive waking-up from a sleep mode.

7. The method of claim 1, further comprising determining whether the code module to be retrieved has a corresponding copied code module stored in the second memory.

8. The method of claim 1, further comprising storing the retrieved code module in a buffer memory.

9. The method of claim 1, further comprising adjusting bandwidth used for retrieving a code module from the second memory.

10. The method of claim 1, wherein the preset rule directs the retrieving operation to the copied code module when the copied code module is present, otherwise to the original code modules.

11. The method of claim 1, further comprising identifying locations of the original and copied code modules in the first and second memories.

12. An optical drive, comprising:
a first memory storing a plurality of original code modules;
a second memory storing a copied code module duplicated from one of the original code modules;
a microprocessor retrieving code modules from either the first memory or second memory and executing the retrieved code modules; and
a retrieval controller directing the microprocessor to retrieve the code modules according to a preset rule.

13. The optical drive of claim 12, wherein the first memory is a serial flash ROM.

14. The optical drive of claim 12, wherein the second memory is a random access memory (RAM).

15. The optical drive of claim 12, wherein the second memory is redownloaded in response to a predetermined event.

16. The optical drive of claim 15, wherein the predetermined event is initiation of the optical drive.

17. The optical drive of claim 15, wherein the predetermined event is the optical drive waking-up from a sleep mode.

18. The optical drive of claim 12, wherein the retrieval controller further determines whether the code module to be retrieved has a corresponding copied code module in the second memory.

19. The optical drive of claim 12, further comprising a buffer memory temporarily storing the retrieved code module.

20. The optical drive of claim 12, wherein the retrieval controller further adjusts bandwidth used for retrieving the copied code module from the second memory.

21. The optical drive of claim 12, wherein the preset rule directs the microprocessor to retrieve the copied code module when the copied code module is present.

22. A method of operating an optical drive comprising a memory, comprising:
performing basic operations according to a basic firmware;
determining whether a needed operational firmware is present in the memory;
receiving data comprising the needed operational firmware from a host;
storing the received data in the memory; and
executing the operational firmware stored in the memory.

23. The method of claim 22, wherein the basic operations are executed according to basic firmware stored in a non-volatile memory of the optical drive.

24. The method of claim 23, further comprising establishing a firmware map identifying locations of the basic firmware and the operational firmware in the non-volatile memory and the memory, respectively.

25. The method of claim 22, wherein the basic firmware is received from the host.

26. The method of claim 25, wherein the basic operations are executed according to the basic firmware stored in the memory.

27. The method of claim 22, wherein the basic operations configure the optical drive for firmware input.

28. The method of claim 22, further comprising determining characteristics of the media.

29. The method of claim 22, further comprising notifying the host of the absence of the operational firmware.

30. The method of claim 22, further comprising performing an error check on the received operational firmware.

31. The method of claim 22, wherein the determining step further specifies that media is present.

32. The method of claim 22, wherein the determining step further specifies that media is changed.

33. An optical drive, comprising:
a processor executing basic operations, determining whether a needed operational firmware is present in the memory;
an interface receiving the operational firmware from a host; and
a memory storing the received operational firmware directing the processor to operate.

34. The optical drive of claim 33, further comprising a non-volatile memory storing a basic firmware directing the basic operations.

35. The optical drive of claim 34, wherein the processor establishes a firmware map identifying locations of the basic firmware and the operational firmware in the non-volatile memory and the memory, respectively.

36. The optical drive of claim 33, wherein the basic operations are executed according to the basic firmware received from the host.

37. The optical drive of claim 33, wherein the received basic firmware is stored in the memory.

38. The optical drive of claim 33, wherein the basic operations configure the optical drive for firmware input.

39. The optical drive of claim 33, wherein the processor further executes the operational firmware stored in the memory.
